(19) United States
(12) Patent Application Publication
(10) Pub. No.: US 2018/0073140 A1
(43) Pub. Date: Mar. 15, 2018

(54) AUTOMATED PROCESS CONTROL OF ATOMIC LAYER DEPOSITION OF TITANIUM NITRIDE THROUGH TREATMENT GAS PULSE TIME

(71) Applicant: Samsung Electronics Co., Ltd., Suwon-si (KR)

(72) Inventors: David J. WILLIAMS, Pflugerville, TX (US); William Kyle GOULD, Bastrop, TX (US)

(21) Appl. No.: 15/261,655

(22) Filed: Sep. 9, 2016

(51) Int. Cl. C23C 16/455; C23C 16/52; C23C 16/34

(52) U.S. Cl. CPC C23C 16/45525; H01L 21/28556; C23C 16/34; C23C 16/52

(57) ABSTRACT

Methods are disclosed for depositing titanium nitride (TiN) on a substrate in a chamber by exposing the substrate to titanium tetrachloride (TiCl₄) in a chamber, purging the titanium tetrachloride (TiCl₄) from the chamber, exposing the substrate to ammonia (NH₃), and then purging the ammonia (NH₃) from the chamber. Each of these steps is accomplished under various process variables that remain constant when the steps are repeated except for the period of time for exposure of the substrate to the ammonia (NH₃).

### TECHNICAL FIELD

THE PRESENT DISCLOSURE RELATES TO METHODS FOR DEPOSITING TITANIUM NITRIDE (TIN) ON A SUBSTRATE IN A CHAMBER.

### BACKGROUND

An atomic layer deposition (ALD) process is grown through multiple cycles of precursor gas flow then treatment gas flow. For example, the process may include a cycle of exposing a substrate in a chamber to titanium tetrachloride (TiCl₄), purging the titanium tetrachloride (TiCl₄), exposing the substrate to ammonia (NH₃), and then purging the ammonia (NH₃) from the chamber. This series of steps is referred to as a cycle. The combination of precursor and treatment is the industry standard for thickness control of the ALD of TiN. The addition or subtraction of a cycle of deposition is used to alter the thickness of the deposition. For a thin ALD of TiN, a full cycle of deposition results in a thickness adjustment of between 0.20-0.50 Å/cycle. The relatively large size of this thickness adjustment limits the ability to target and match thickness on a single chamber. Variation is increased further when multiple miss-targeted chambers are run simultaneously. With the high sensitivity of threshold voltage (Vₜ) to thickness, the inability to tightly control thickness impacts parametric limited yield (PLY).

The cycle has to be repeated multiple times to get the desired thickness. The number of times it is repeated is referred to as a cycle count. The cycle count is the standard method for adjusting thickness. This cycle is depicted in FIG. 1.

In addition to the standard method for adjusting thickness through a full deposition cycle adjustment, other prior art methods are known. For example, another method involves adjusting deposition rate through modification of a process input variable such as the temperature while keeping the number of cycles constant.

### SUMMARY

Prior art methods of adjusting the number of deposition cycles keeps the deposition rate and film properties constant, but causes step function thickness changes. The thickness adjustment capabilities are limited by the deposition rate per cycle. The higher the deposition rate, the lower the ability to accurately adjust thickness.

Prior art methods of adjusting temperature cause thickness change through deposition rate modification, but has a higher potential of impacting film composition and within wafer uniformity. A known side-effect of temperature adjustments on ALD of TiN is modification of the thickness profile within the wafer. Additionally, this prior art method requires stabilization time, which decreases manufacturability.

Exemplary embodiments of the inventive concept provide improved methods for depositing titanium nitride (TiN) on a substrate in a chamber. The method comprises depositing a monolayer of titanium nitride (TiN) on a substrate in a chamber, which includes exposing the substrate to ammonia (NH₃) in a chamber for a period of time that is set within a range of 0.20 seconds to 0.40 seconds to yield a desired thickness of the monolayer of titanium nitride (TiN) or within a range of 0.25 seconds to 0.35 seconds. After the monolayer has been deposited, the thickness of the monolayer of titanium nitride (TiN) is measured and then the thickness of the monolayer of titanium nitride (TiN) is compared with the desired thickness for the monolayer of titanium nitride (TiN). In the next step, the period of time is adjusted that was set for exposing the substrate to ammonia (NH₃) in the chamber if the thickness of the monolayer of titanium nitride (TiN) as measured is not the same as the desired thickness of the monolayer of titanium nitride (TiN). Finally, an automated feedback loop is used to repeat the steps of depositing a monolayer of titanium nitride (TiN), measuring the thickness of the monolayer, comparing the measured thickness with a desired thickness of the monolayer of titanium nitride (TiN), and adjusting the period of time that is set for exposing the substrate to ammonia (NH₃) in the chamber within a range of 0.20 seconds to 0.40 seconds or within a range of 0.25 seconds to 0.35 seconds if the thickness of the monolayer of titanium nitride (TiN) as measured is not the same as the desired thickness of the monolayer of titanium nitride (TiN).

Depositing a monolayer of titanium nitride (TiN) on a substrate in a chamber, also comprises additional steps in addition to exposing the substrate to ammonia (NH₃) in the chamber for a period of time that is set within a range of 0.20 seconds to 0.40 seconds or within a range of 0.25 seconds to 0.35 seconds to yield a desired thickness of the monolayer of titanium nitride (TiN). Prior to exposing the substrate to ammonia (NH₃), the substrate has been exposed to a titanium source such as titanium tetrachloride (TiCl₄) in the chamber for a period of time and the titanium tetrachloride (TiCl₄) has then been purged. After the substrate has been exposed to the ammonia (NH₃), the ammonia (NH₃) is purged from the chamber.

The method enables a high level of control to be achieved with respect to the thickness by utilizing a small change in the deposition rate caused by an adjustment of the precursor flow namely the ammonia (NH₃). This flow may be adjusted through an automated feedback loop to provide superior process control. The function of thickness control through the duration of the precursor gas flow is achieved while keeping other process input variables, such as temperature, constant. Targeting is maintained through the use of the adjustment of the amount of time for the deposition and its control via automated process control. The difference between the first deposition rate for a first monolayer of titanium nitride (TiN) after adjusting the period of time that is set for exposing the substrate to ammonia (NH₃) in the chamber results in a second monolayer being deposited at a second deposition rate that differs from the first deposition rate in an amount ranging from about 0.001 Å/sec to about 0.2 Å/sec.

Thickness can be adjusted on a continuous scale to the point that metrology is the limiting factor to thickness control. Additionally, there is no impact to film composition or within wafer uniformity.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, as listed below.

FIG. 1 is a flow chart of a prior art cycle.

FIG. 2 is a flow chart of a continuous feedback loop used to automatically adjust the amount of time for the exposure of the substrate to the ammonia (NH₃).

FIG. 3 is a schematic depiction of an embodiment of a system used in conjunction with the disclosed methods.

FIG. 4 is a chart depicting the thickness of a deposited monolayer versus the ammonia (NH₃) pulse time.

FIG. 5 is a chart depicting the percentage of standard deviation versus the ammonia (NH₃) pulse time.

FIG. 6 is a chart depicting the percentage of titanium versus the ammonia (NH₃) pulse time.

FIG. 7 is a chart depicting the ammonia (NH₃) flow time dependence as a function of sheet resistance Rₛ (ohms/square).

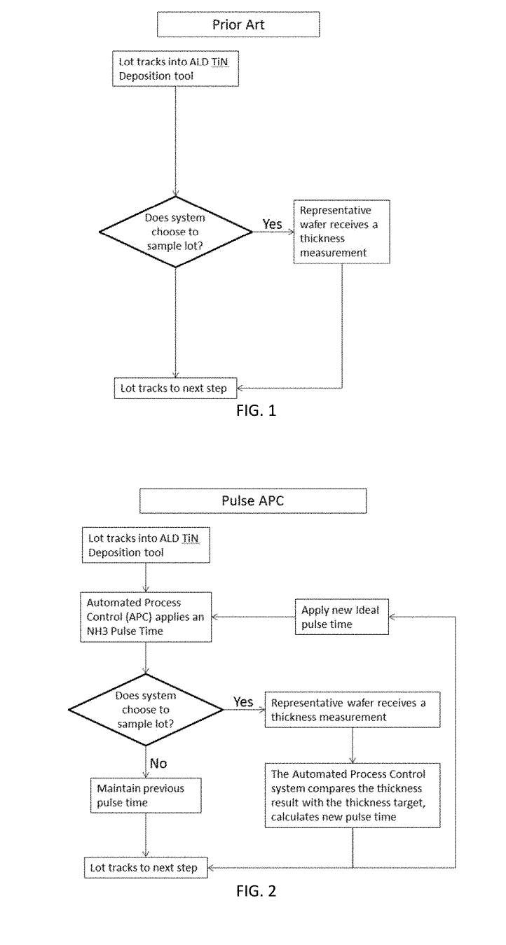

### DETAILED DESCRIPTION OF THE PREFERRED EMBODIMENTS

Various exemplary embodiments will be described more fully hereinafter with reference to the accompanying drawings. The present inventive concept may, however, be embodied in many alternate forms and should not be construed as limited to the example embodiments set forth herein. Rather, these example embodiments are provided so that this description will be thorough and complete, and will fully convey the scope of the present inventive concept to those skilled in the art.

The method comprises depositing a monolayer of titanium nitride (TiN) on a substrate in a chamber. This is achieved by exposing the substrate to titanium tetrachloride (TiCl₄) in a chamber, purging the titanium tetrachloride (TiCl₄) from the chamber to prevent a gas-phase reaction that could lead to defects or non-uniform film thickness, exposing the substrate to ammonia (NH₃) (also referred to herein as treatment gas), and then purging the ammonia (NH₃) from the chamber out to prevent a gas-phase reaction. These steps are collectively referred to as a cycle. Each of these steps is accomplished under various process variables such as a temperature and a period of time. The substrate is exposed to the ammonia (NH₃) for a period of time that is set within a range of 0.20 seconds to 0.40 seconds or within a range of 0.25 seconds to 0.35 seconds to yield a desired thickness of the monolayer of titanium nitride (TiN). Shortening the pulse decreases the thickness of the monolayer and lengthening the pulse increases the thickness of the monolayer. As depicted in FIG. 2, a continuous feedback loop is used to automatically adjust the amount of time for the exposure of the substrate to the ammonia (NH₃) prior to repeating the step of depositing a monolayer of titanium nitride (TiN) on a substrate in a chamber. All of the other process variables may remain constant.

The continuous feedback loop includes measuring the thickness of the monolayer of titanium nitride (TiN), comparing the thickness of the monolayer of titanium nitride (TiN) with the desired thickness for the monolayer of titanium nitride (TiN), and adjusting the period of time that was set for exposing the substrate to ammonia (NH₃) in the chamber if the thickness of the monolayer of titanium nitride (TiN) as measured is not the same as the desired thickness of the monolayer of titanium nitride (TiN). As shown in FIG. 2, the previous pulse time is maintained when the measured thickness is the same as the desired thickness. When the thickness of the monolayer of titanium nitride (TiN) as measured is not the same as the desired thickness of the monolayer of titanium nitride (TiN), the steps are repeated with the adjusted period of time for exposing the substrate to the ammonia (NH₃). The period of time that is set for exposing the substrate to ammonia (NH₃) in the chamber may be adjusted in an increment of 0.01 seconds within the range of 0.20 seconds to 0.40 seconds or within a range of 0.25 seconds to 0.35 seconds. Smaller increments than 0.01 seconds may also be used. When a monolayer of titanium nitride (TiN) is deposited on a substrate and another monolayer is subsequently deposited with a different deposition rate due to the amount of exposure time, the difference in deposition rate may range from about 0.001 Å/sec to about 0.003 Å/sec. When an incremental adjustment of 0.01 seconds is made then the change in deposition rate is about 0.2 Å/second or 0.002 Å. For example, an increase of 0.01 seconds of pulse time results in a deposition rate increase from 0.280 Å/cycle to 0.282 Å/cycle and at 60 cycles the 0.01 seconds adjustment would increase thickness by 0.12 Å while at 250 cycles that same adjustment would yield a thickness increase of 0.50 Å. Because the resulting thickness change could range from about 0.10 Å for a 60 cycle recipe to about 0.60 Å for a 250 cycle recipe, this is a substantial improvement in accuracy over the prior art methods, which resulted in a thickness adjustment of between 0.20-0.50 Å/cycle.

Maintaining all of the process variables constant with respect to each cycle except for the period of time set for exposing the substrate to ammonia (NH₃) in the chamber enables several additional benefits. For example, the same variable can be simultaneously extended to multiple recipes. This allows all recipes that use that variable to be simultaneously adjusted. Because each chamber has a unique variable, chambers may be separately targeted. Additionally, the variable can be accessed by recipe management to allow automated process control. The method enables automated process control to maintain a constant deposition rate and film properties across multiple thickness recipes simultaneously to provide electrical parameter stability. Further, thickness variations are avoided that are based chamber variations. Because the deposition rate is maintained across all thickness variations of a recipe on a chamber, recipes can be changed on a lot-by-lot (or wafer-to-wafer) basis to compensate for upstream shifts and to improve device targeting.

Work function metal thickness control maintains a stable PLY. Conventional thickness adjustment methods are insufficient for maintaining tight process control as the deposition rate drops throughout a maintenance cycle. Conventional deposition cycle adjustments cause large thickness shifts and do not permit small thickness increments. Similarly, use of conventional precursor or pedestal temperature adjustments are inconsistent, require manual calculation and adjustment, take time to stabilize, and can change film properties. If the adjustment under or over-compensates, another adjustment and stabilization is required. Additionally, process control degrades further as multiple chambers with different deposition rates are all processing simultaneously using conventional methods.

Deposition rate adjustments through precursor pulse duration allow a real-time, automated, nearly-continuous thickness adjustment method. Additionally, small adjustments allow thickness targeting within the capability of a metrology tool. Further, all chambers can be tuned to have the same deposition rate, allowing nearly identical performance across a fleet of tools. Importantly, these objectives are achieved without changes to film properties.

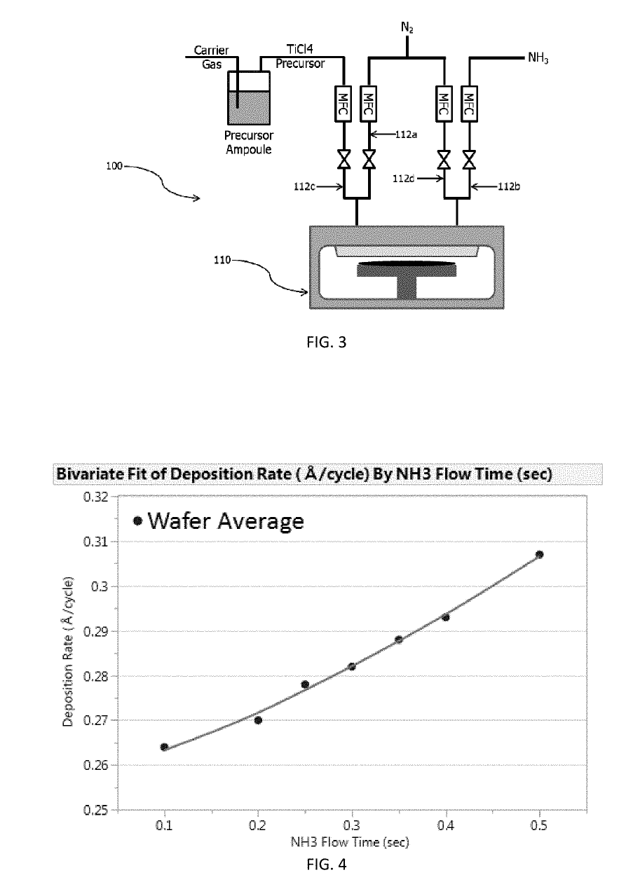

FIG. 3 depicts a system 100 used in conjunction with the method. Reaction chamber 100 has gas lines 112a-d that respectively deliver the N₂, NH₃, TiCl₄, and N₂ gases. The gases are delivered via the gas lines 112a-d and are controlled by valves to either flow into the reactor or to be diverted.

In one embodiment, the substrate is exposed to titanium tetrachloride (TiCl₄) in a chamber for an amount of time ranging from about 0.02 seconds to about 1.0 seconds, from 0.02 seconds to about 0.15 seconds, from about 0.15 seconds to about 1.0 seconds, or about 0.05 seconds. The titanium tetrachloride (TiCl₄) may be purged from the chamber for about 0.2 seconds. The substrate may be exposed to ammonia (NH₃) for about 0.3 seconds. The ammonia (NH₃) may then be purged from the chamber for about 0.3 seconds. The pulse duration of the ammonia (NH₃) is then varied to increase up to about 0.40 seconds or decreased down to 0.20 seconds as needed in increments of 0.01 seconds. Another process variable for the method may include a temperature ranging from about 350° C. to about 550° C. The titanium tetrachloride (TiCl₄) may flow at a rate in range from about 10 standard cubic centimeters per minute (sccm) to about 70 sccm. The ammonia (NH₃) may flow at a rate in range from about 1000 sccm to about 3000 sccm. The exhaust pressure from the chamber may range from about to 2 to about 7 Torr. With the exception of the thickness control through the precursor gas flow duration, these process variables may remain constant when a cycle is repeated.

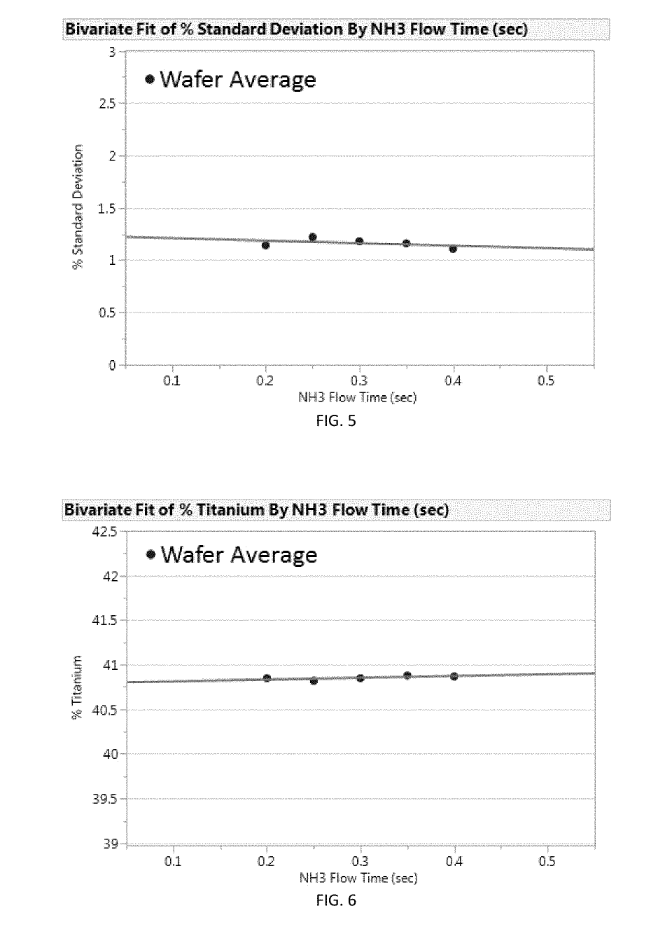

A high level of thickness control can be achieved by utilizing the small change in deposition rate caused by an adjustment of either the treatment flow. FIGS. 4-6 are charts showing the benefits of setting the period of time for exposing the substrate to ammonia (NH₃) in the chamber within the range of 0.20 seconds to 0.40 seconds and making adjustments in an increment of 0.01 seconds. FIG. 4 shows the thickness of deposited monolayer versus the ammonia (NH₃) pulse time. The pulse deposition rate is shown to be nearly linear within the process window of 0.20 seconds to 0.40 seconds. FIG. 5 shows the percentage of standard deviation versus the ammonia (NH₃) pulse time. Within the wafer the percentage of standard deviation was nearly linear within the process window of 0.20 seconds to 0.40 seconds. FIG. 6 shows the percentage of titanium versus the ammonia (NH₃) pulse time. The titanium concentration was nearly linear within the process window of 0.20 seconds to 0.40 seconds.

### EXAMPLES OF THE DISCLOSED EMBODIMENTS

The following are several examples of methods for depositing titanium nitride (TiN) on a substrate in a chamber. Such exemplary formulations and manufacturing conditions are given by way of example, and not by limitation, in order to illustrate compositions that have been found to be useful.

The recipe sequence included the substrate being exposed to titanium tetrachloride (TiCl₄) in a chamber for 0.05 seconds, the titanium tetrachloride (TiCl₄) being purged from the chamber for 0.2 seconds, the substrate being exposed to ammonia (NH₃) for about 0.3 seconds, and the ammonia (NH₃) being purged from the chamber for 0.3 seconds. The method was conducted at a temperature in the chamber of 440° C. The flow rates for the titanium tetrachloride (TiCl₄), ammonia (NH₃), and N2 were respectively 50 sccm, 2700 sccm, and 3000 sccm. The exhaust pressure from the chamber was 3 Torr. The number of cycles totaled 182 to achieve a deposition thickness of 5 nm.

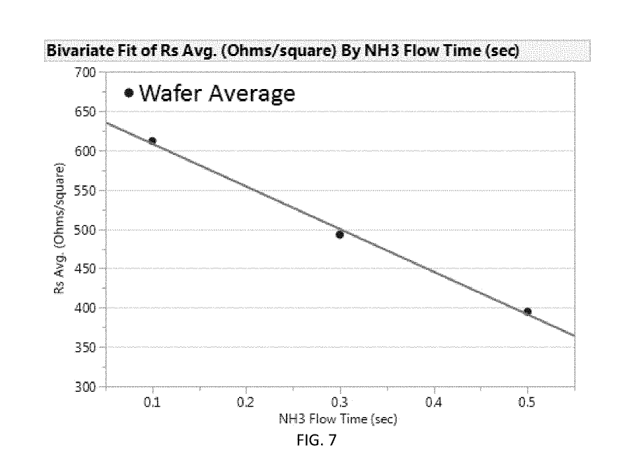

Variations were then made and the results are reported in the chart provided as FIG. 7. The main conditions that are listed above are shown in each chart as the center data point and then a process variable was decreased and increased as shown. FIG. 7 shows a variable as a function of Rₛ (ohms/square). In particular, FIG. 7 shows the ammonia (NH₃) flow time dependence. This chart shows that varying the exposure time for the ammonia (NH₃) delivers the optimal results.

Any methods disclosed herein comprise one or more steps or actions for performing the described method. The method steps and/or actions may be interchanged with one another. In other words, unless a specific order of steps or actions is required for proper operation of the embodiment, the order and/or use of specific steps and/or actions may be modified. Recitation in the claims of the term “first” with respect to a feature or element does not necessarily imply the existence of a second or additional such feature or element.

References to approximations are made throughout this specification, such as by use of the terms “about” or “approximately.” For each such reference, it is to be understood that, in some embodiments, the value, feature, or characteristic may be specified without approximation. For example, where qualifiers such as “about,” “substantially,” and “generally” are used, these terms include within their scope the qualified words in the absence of their qualifiers.

Reference throughout this specification to “an embodiment” or “the embodiment” means that a particular feature, structure or characteristic described in connection with that embodiment is included in at least one embodiment. Thus, the quoted phrases, or variations thereof, as recited throughout this specification are not necessarily all referring to the same embodiment.

Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, as the following claims reflect, inventive aspects lie in a combination of fewer than all features of any single foregoing disclosed embodiment.

The claims following this written disclosure are hereby expressly incorporated into the present written disclosure, with each claim standing on its own as a separate embodiment. This disclosure includes all permutations of the independent claims with their dependent claims. Moreover, additional embodiments capable of derivation from the independent and dependent claims that follow are also expressly incorporated into the present written description. These additional embodiments are determined by replacing the dependency of a given dependent claim with the phrase “any of the preceding claims up to and including claim [x],” where the bracketed term “[x]” is replaced with the number of the most recently recited independent claim. For example, for the first claim set that begins with independent claim 1, claim 3 can depend from either of claims 1 and 2, with these separate dependencies yielding two distinct embodiments; claim 4 can depend from any one of claim 1, 2, or 3, with these separate dependencies yielding three distinct embodiments; claim 5 can depend from any one of claim 1, 2, 3, or 4, with these separate dependencies yielding four distinct embodiments; and so on.

Embodiments of the invention in which an exclusive property or privilege is claimed are defined as follows.

1. A method of setting a pulse for depositing titanium nitride (TiN) in a chamber, the method comprising:
(a) depositing a monolayer of titanium nitride (TiN) on a substrate by exposing the substrate to ammonia (NH3) in the chamber for a period of time that is set within a range of 0.20 seconds to 0.40 seconds;
(b) measuring a thickness of the monolayer of titanium nitride (TiN);
(c) comparing the thickness of the monolayer of titanium nitride (TiN) with a desired thickness for the monolayer of titanium nitride (TiN);
(d) adjusting the period of time to an adjusted period of time in response to a comparison result of the comparing the thickness of the monolayer of titanium nitride (TiN) with the desired thickness for the monolayer of titanium nitride (TiN), wherein the adjusted period of time is within a range of 0.2 seconds to 0.40 seconds; and
(e) repeating steps (a)-(d) until the thickness of the monolayer of titanium nitride (TiN) as measured is approximately the same as the desired thickness of the monolayer of titanium nitride (TiN).

2. The method of claim 1,
wherein the monolayer of titanium nitride (TiN) deposited on a substrate is a first monolayer and is deposited at a first deposition rate; and
wherein the period of time that is set for exposing the substrate to ammonia (NH3) in the chamber is adjusted in an increment, in response to the comparison result, that results in a second monolayer being deposited at a second deposition rate that differs from the first deposition rate in an amount ranging from about 0.001 Å/sec to about 0.2 Å/sec.

3. The method of claim 1,
wherein the adjusting of the period of time is performed in an increment of 0.01 seconds.

4. The method of claim 1,
wherein in the repeating of the steps (a)-(d), all process variables except for the period of time remain the same in the depositing of the monolayer of titanium nitride (TiN).

5. The method of claim 1,
wherein exposing the substrate to ammonia (NH3) in the chamber occurs at a temperature, and
wherein in the repeating of the steps (a)-(d), the temperature remains the same.

6. The method of claim 1,
wherein the chamber operates at a temperature during step (a), and
wherein in the repeating of the steps (a)-(d), the temperature remains unchanged.

7. A method of depositing titanium nitride (TiN) on a substrate in a chamber, the method comprising:
(a) depositing a monolayer of titanium nitride (TiN) on the substrate,
wherein the depositing of the monolayer of the titanium nitride (TiN) includes:
exposing the substrate to titanium tetrachloride (TiCl4) in the chamber for a period of time;
purging the titanium tetrachloride (TiCl4) from the chamber for a period of time;
exposing the substrate to ammonia (NH3) in the chamber for a period of time that is set within a range of 0.20 seconds to 0.40 seconds; and
purging the ammonia (NH3) from the chamber for a period of time;
(b) measuring a thickness of the monolayer of titanium nitride (TiN);
(c) comparing the thickness of the monolayer of titanium nitride (TiN) with a desired thickness for the monolayer of titanium nitride (TiN);
(d) adjusting the period of time that is set for exposing the substrate to ammonia (NH3) in the chamber to an adjusted period of time in response to a comparison result of the comparing of the thickness of the monolayer of titanium nitride (TiN) with the desired thickness, wherein the adjusted period of time is within a range of 0.20 seconds to 0.40 seconds; and
(e) repeating steps (a)-(d) until the thickness of the monolayer of titanium nitride (TiN) as measured is approximately the same as the desired thickness of the monolayer of titanium nitride (TiN).

8. The method of claim 7,
wherein the monolayer of titanium nitride (TiN) deposited on a substrate is a first monolayer and is deposited at a first deposition rate; and
wherein the period of time that is set for exposing the substrate to ammonia (NH3) in the chamber is adjusted in an increment, in response to the comparison result, that results in a second monolayer being deposited at a second deposition rate that differs from the first deposition rate in an amount ranging from about 0.001 Å/sec to about 0.2 Å/sec.

9. The method of claim 7,
wherein the period of time that is set for exposing the substrate to ammonia (NH3) in the chamber is adjusted in an increment of 0.01 seconds within the range of 0.20 seconds to 0.40 seconds.

10. The method of claim 7,
wherein in the repeating of the steps (a)-(d), all process variables except for the period of time remain the same in the depositing of the monolayer of titanium nitride (TiN).

11. The method of claim 7,
wherein in the repeating of the steps (a)-(d), the period of time for exposing the substrate to titanium tetrachloride in a chamber, the period of time for purging the titanium tetrachloride (TiCl4) from the chamber, and the period of time for purging the ammonia (NH3) from the chamber each remain the same.

12. The method of claim 7,
wherein exposing the substrate to ammonia (NH3) in the chamber occurs at a temperature; and
wherein in the repeating of the steps (a)-(d), the temperature remains the same.

13. The method of claim 7,
wherein the exposing of the substrate to titanium tetrachloride occurs at a first temperature, the purging of the titanium tetrachloride (TiCl4) occurs at a second temperature, and the purging of the ammonia (NH3) occurs at a third temperature, and
wherein in the repeating of the steps (a)-(d), the first temperature, the second temperature and the third temperature remain the same.

14. The method of claim 7,
wherein the chamber operates at a temperature during step (a), and
wherein in the repeating of the steps (a)-(d), the temperature remains unchanged.

15. A method of depositing titanium nitride (TiN) on a substrate in a chamber, the method comprising:
(a) depositing a monolayer of titanium nitride (TiN) on the substrate,
wherein the depositing of the monolayer of titanium nitride (TiN) includes:
exposing the substrate to titanium tetrachloride (TiCl4) in the chamber under various process variables including a temperature and a period of time;
purging the titanium tetrachloride (TiCl4) from the chamber under various process variables including a temperature and a period of time; and
exposing the substrate to ammonia (NH3) in the chamber under various process variables including a temperature and a period of time that is set within a range of 0.20 seconds to 0.40 seconds to yield a desired thickness of the monolayer of titanium nitride (TiN); and
purging the ammonia (NH3) under various process variables including a temperature and a period of time;
(b) measuring a thickness of the monolayer of titanium nitride (TiN);
(c) comparing the thickness of the monolayer of titanium nitride (TiN) with the desired thickness for the monolayer of titanium nitride (TiN);
(d) adjusting the period of time that is set for the exposing of the substrate to ammonia (NH3) to an adjusted period of time that is within a range of 0.20 seconds to 0.40 seconds in response to a comparison result of step (c); and
(e) repeating steps (a)-(d) until the thickness of the monolayer of titanium nitride (TiN) as measured is approximately the same as the desired thickness of the monolayer of titanium nitride (TiN),
wherein in the repeating of the steps (a)-(d), all process variables except for the period of time remain the same in the depositing of the monolayer of titanium nitride (TiN).

16. The method of claim 15,
wherein the monolayer of titanium nitride (TiN) deposited on a substrate is a first monolayer and is deposited at a first deposition rate; and
wherein the period of time that is set for exposing the substrate to ammonia (NH3) in the chamber is adjusted in an increment, in response to the comparison result, that results in a second monolayer being deposited at a second deposition rate that differs from the first deposition rate in an amount ranging from about 0.001 Å/sec to about 0.2 Å/sec.

17. The method of claim 15,
wherein the period of time that is set for exposing the substrate to ammonia (NH3) in the chamber is adjusted in an increment of 0.01 seconds within the range of 0.20 seconds to 0.40 seconds.
